(19) United States
(12) Patent Application Publication
(10) Pub. No.: US 2026/0344191 A1
(43) Pub. Date: Oct. 29, 2026

(54) DISPLAY PANEL AND DISPLAY APPARATUS

(71) Applicants: Chengdu BOE Optoelectronics Technology Co., Ltd., Chengdu, Sichuan (CN); BOE Technology Group Co., Ltd., Beijing (CN)

(72) Inventors: Langtao LI, Beijing (CN); Kening ZHENG, Beijing (CN); Dengyu WANG, Beijing (CN); Xuenan PAN, Beijing (CN); Tong WU, Beijing (CN)

(73) Assignees: Chengdu BOE Optoelectronics Technology Co., Ltd., Chengdu, Sichuan (CN); BOE Technology Group Co., Ltd., Beijing (CN)

(21) Appl. No.: 19/148,385

(22) PCT Filed: Aug. 19, 2024
(86) PCT No.: PCT/CN2024/113208

§ 371 Date: Jul. 16, 2025

(30) Foreign Application Priority Data
Mar. 27, 2024 (CN) 202410361756.2

(51) Int. Cl. H10K 59/122; H10K 59/80

(52) U.S. Cl. CPC H10K 59/122; H10K 59/80515

(57) ABSTRACT

A display panel includes a plurality of rectangular sub-pixel regions, each sub-pixel region includes a light-emitting region and an avoidance region that are adjacent and connected to each other. The display panel includes: a substrate; a driving circuit layer; a plurality of pixel electrodes; a pixel definition structure, the pixel definition structure being provided therein with a pixel opening in the light-emitting region, and a shape of the pixel opening being the same as a shape of the light-emitting region; and a plurality of light-emitting portions, one light-emitting portion being arranged in one pixel opening. One pixel opening corresponds to one pixel electrode. The pixel electrode includes a main body and a connection portion. A shape of the main body is the same as the shape of the pixel opening. The connection portion is located in the avoidance region, and the connection portion is connected to the driving circuit layer.

### CROSS-REFERENCE TO RELATED APPLICATIONS

This application is a national phase entry under 35 USC 371 of International Patent Application No. PCT/CN2024/113208, filed on Aug. 19, 2024, which claims priority to Chinese Patent Application No. 202410361756.2, filed on Mar. 27, 2024, which are incorporated herein by reference in their entirety.

### TECHNICAL FIELD

The present disclosure relates to the field of display technologies, and in particular, to a display panel and a display apparatus.

### BACKGROUND

Organic light-emitting diode (OLED) is a new generation of display technology that has developed rapidly in recent years, and it has been widely used in many fields such as flat panel display, flexible display, vehicle-mounted display and solid-state lighting due to its advantages such as self-luminescence, fast response, high luminous efficiency and brightness, ultra-small thickness, wide viewing angle, wide operating temperature range, simple production process, low power consumption and flexibility.

### SUMMARY

In an aspect, a display panel is provided. The display panel includes a plurality of rectangular sub-pixel regions, each sub-pixel region includes a light-emitting region and an avoidance region that are adjacent and connected to each other, the avoidance region includes a vertex corner of a rectangle, and a region of the rectangle other than the avoidance region is the light-emitting region. The display panel includes a substrate, a driving circuit layer, a pixel definition layer, a plurality of pixel electrodes, and a plurality of light-emitting portions. The driving circuit layer is disposed on the substrate. The plurality of pixel electrodes are disposed on a side of the driving circuit layer away from the substrate. The pixel definition structure is disposed on a side of the plurality of pixel electrodes away from the driving circuit layer. The pixel definition structure is provided therein with a pixel opening in the light-emitting region, and a shape of the pixel opening is the same as a shape of the light-emitting region. One light-emitting portion is disposed in one pixel opening. One pixel opening corresponds to one pixel electrode, the pixel electrode includes a main body and a connection portion that are connected to each other, a shape of the main body is the same as the shape of the pixel opening, the connection portion is located in the avoidance region, and the connection portion is connected to the driving circuit layer.

In some embodiments, a boundary of the main body includes two perpendicular edges and a set edge that are connected, ends of the two perpendicular edges are connected and form a right angle, two ends of the two perpendicular edges that are far away from each other are respectively connected to two ends of the set edge, and the set edge includes an arc segment; an end of the connection portion is connected to the arc segment of the boundary of the main body; and another end of the connection portion extends in a direction away from the main body and is connected to the driving circuit layer.

In some embodiments, two ends of the arc segment are respectively connected to the two ends of the two perpendicular edges that are far away from each other.

In some embodiments, the set edge further includes two straight segments, the two straight segments are respectively located on two ends of the arc segment, and a straight segment is connected to an end of the arc segment and an end of one of the two perpendicular edges.

In some embodiments, a radius of curvature of the arc segment is less than or equal to a size of a perpendicular edge of the two perpendicular edges.

In some embodiments, an orthographic projection of the main body on the substrate is fan-shaped or approximately fan-shaped, or is in a shape of a pentagon obtained by cutting off a corner of a rectangle.

In some embodiments, the display panel includes a plurality of pixel units, each pixel unit includes four sub-pixels, the four sub-pixels are arranged in a 2×2 matrix, and each sub-pixel includes a pixel electrode and a corresponding light-emitting portion; set edges of main bodies of pixel electrodes of the four sub-pixels are close to each other and enclose an accommodation region; and connection portions of the pixel electrodes of the four sub-pixels are arranged close to each other and are located in the accommodation region.

In some embodiments, a shape formed by a line connecting an end of each of the connection portions of the four sub-pixels that is away from a respective main body is a square.

In some embodiments, the display panel includes a plurality of pixel unit, each pixel unit includes four sub-pixels, the four sub-pixels are arranged in a 2×2 matrix, and each sub-pixel includes a pixel electrode and a corresponding light-emitting portion; along a circumferential direction around a center of the pixel unit, main bodies and connection portions of four pixel electrodes of the four sub-pixels are arranged alternately.

In some embodiments, a connection portion extends along a tangential direction of the circumferential direction around the center of the pixel unit.

In some embodiments, among the pixel electrodes of the four sub-pixels, at least a pair of two adjacent pixel electrodes are symmetrically arranged with respect to a reference line; and the reference line is a bisector being perpendicular to a direction in which the two adjacent pixel electrodes are arranged and being located between the two adjacent pixel electrodes.

In some embodiments, each pixel unit includes at least a first sub-pixel and a second sub-pixel that emit light of a same color, and the first sub-pixel and the second sub-pixel are respectively distributed at two adjacent vertex corners in the pixel unit.

In some embodiments, each pixel unit includes at least a first sub-pixel and a second sub-pixel that emit light of a same color, and the first sub-pixel and the second sub-pixel are respectively distributed at two opposite corners in the pixel unit.

In some embodiments, the display panel further includes: an insulating dielectric layer located between the driving circuit layer and the pixel electrodes. The insulating dielectric layer is provided therein with a via hole, the connection portion is connected to the driving circuit layer through the via hole, and the via hole is located in the avoidance region.

In another aspect, a display apparatus is provided. The display apparatus includes the display panel as described in any one of the above embodiments, and a cover plate disposed on a light-exit side of the display panel.

### BRIEF DESCRIPTION OF THE DRAWINGS

In order to describe technical solutions in the present disclosure more clearly, the accompanying drawings to be used in some embodiments of the present disclosure will be introduced briefly. However, the accompanying drawings to be described below are merely drawings of some embodiments of the present disclosure, and a person of ordinary skill in the art can obtain other drawings according to those drawings. In addition, the accompanying drawings in the following description may be regarded as schematic diagrams, and are not limitations on actual sizes of products and actual processes of methods involved in the embodiments of the present disclosure.

FIG. 1 is a structural diagram of a display apparatus, in accordance with some embodiments;

FIG. 2 is a structural diagram of a display panel, in accordance with some embodiments;

FIG. 3 is a structural diagram of another display panel, in accordance with some embodiments;

FIG. 4 is a diagram showing a partial structure of a display panel, in accordance with some embodiments;

FIG. 5 is a structural diagram of yet another display panel, in accordance with some embodiments;

FIG. 6A is a structural diagram of yet another display panel, in accordance with some embodiments;

FIG. 6B is a structural diagram of yet another display panel, in accordance with some embodiments;

FIG. 7 is a structural diagram of yet another display panel, in accordance with some embodiments;

FIG. 8 is a structural diagram of yet another display panel, in accordance with some embodiments;

FIG. 9 is a structural diagram of yet another display panel, in accordance with some embodiments; and

FIGS. 10 to 22 are diagram showing structures in processes of manufacturing a display panel, in accordance with some embodiments.

### DETAILED DESCRIPTION

The technical solutions in some embodiments of the present disclosure will be described clearly and completely with reference to the accompanying drawings. However, the described embodiments are merely some but not all embodiments of the present disclosure. All other embodiments obtained by a person of ordinary skill in the art based on embodiments of the present disclosure shall be included in the protection scope of the present disclosure.

Unless the context requires otherwise, throughout the specification and claims, the term “comprise” is construed as an open and inclusive meaning, i.e., “included, but not limited to”. In the description of the specification, the terms such as “one embodiment”, “some embodiments”, “exemplary embodiments”, “example” or “some examples” are intended to indicate that specific features, structures, materials, or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics may be included in any one or more embodiments or examples in any suitable manner.

The terms “first” and “second” are used for descriptive purposes only, and are not to be construed as indicating or implying a relative importance or implicitly indicating the number of indicated technical features. Thus, features defined with “first” or “second” may explicitly or implicitly include one or more of the features. In the description of the embodiments of the present disclosure, the term “multiple”, “a plurality of” or “the plurality of” means two or more unless otherwise specified.

In the description of some embodiments, the expressions “coupled,” “connected,” and derivatives thereof may be used. The term “connected” should be understood in a broad sense. For example, the term “connected” may represent a fixed connection, a detachable connection, or a one-piece connection, or may represent a direct connection, or may represent an indirect connection through an intermediate medium. The term “coupled” indicates that two or more components are in direct physical or electrical contact with each other. The term “coupled” or “communicatively coupled” may also indicate that two or more components are not in direct contact with each other, but still cooperate or interact with each other. The embodiments disclosed herein are not necessarily limited to the content herein.

The phrase “at least one of A, B, and C” has the same meaning as the phrase “at least one of A, B, or C”, both including the following combinations of A, B, and C: only A, only B, only C, a combination of A and B, a combination of A and C, a combination of B and C, and a combination of A, B, and C.

The phrase “A and/or B” includes the following three combinations: only A, only B, and a combination of A and B.

The phrase “applicable to” or “configured to” used herein has an open and inclusive meaning, which does not exclude devices that are applicable to or configured to perform additional tasks or steps.

It will be understood that, when a layer or element is referred to as being on another layer or substrate, it may be that the layer or element is directly on the another layer or substrate, or it may be that intermediate layer(s) exist between the layer or element and the another layer or substrate.

Exemplary embodiments are described herein with reference to sectional views and/or plan views that are schematic illustrations of idealized embodiments. In the drawings, thicknesses of layers and areas of regions are enlarged for clarity. Variations in shape with respect to the accompanying drawings due to, for example, manufacturing technologies and/or tolerances may be envisaged. Therefore, the exemplary embodiments should not be construed as being limited to the shapes of the regions shown herein, but including shape deviations due to, for example, manufacturing. For example, an etched region shown to have a rectangular shape generally has a feature of being curved. Thus, the regions shown in the accompanying drawings are schematic in nature, and their shapes are not intended to show actual shapes of the regions in a device, and are not intended to limit the scope of the exemplary embodiments.

Some embodiments of the present disclosure provide a display apparatus. The display apparatus may be any apparatus that displays an image whether in motion (e.g., a video) or stationary (e.g., a still image), and whether textual or graphical. More specifically, it is expected that the display apparatus in the embodiments may be implemented in or associated with a plurality of electronic devices, and the plurality of electronic devices include (but are not limit to), for example, a mobile phone, a wireless device, a personal digital assistant (PDA), a hand-held or portable computer, a GPS receiver/navigator, a camera, an MP4 video player, a video camera, a game console, a watch, a clock, a calculator, a TV monitor, a flat panel display, a computer monitor, a car display (e.g., an odometer display), a navigator, a cockpit controller and/or display, a display in camera view (e.g., a display for a rear camera in a vehicle), an electronic photo, an electronic billboard or indicator, a projector, a building structure, a packaging, and an aesthetic structure (e.g., a display for an image of a piece of jewelry).

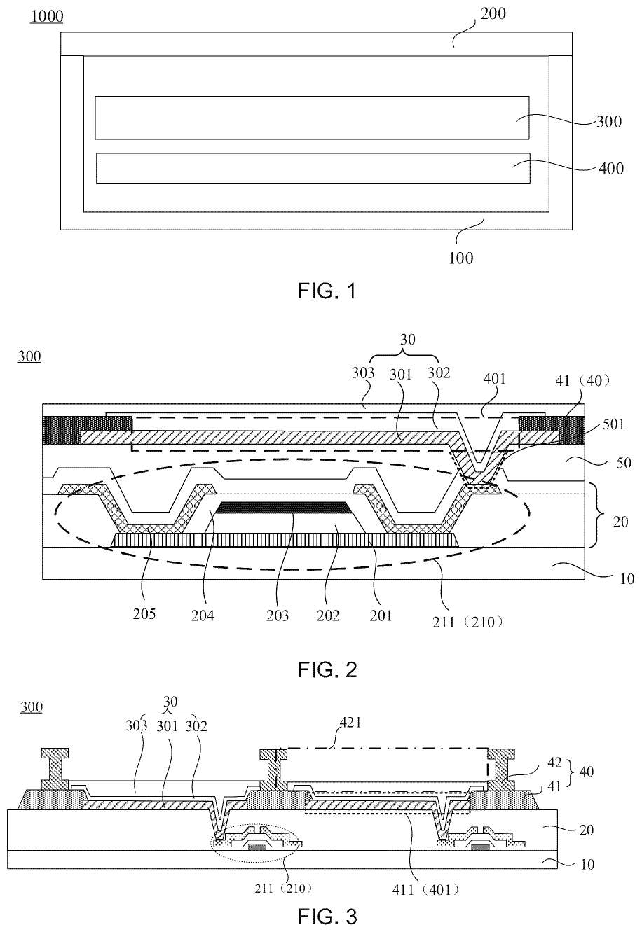

FIG. 1 is a structural diagram of a display apparatus, in accordance with some embodiments. As shown in FIG. 1, the display apparatus 1000 includes a frame 100, a cover plate 200, a display panel 300, a circuit board 400, and other electronic components including a camera.

A longitudinal section of the frame 100 is U-shaped. The display panel 300, the circuit board 400 and other electronic accessories including the camera are disposed inside the frame 100. The circuit board 400 is located between the display panel 300 and the frame 100. The cover plate 200 is located on a light-exit side of the display panel 300. A side of the display panel 300 for displaying images is the light-exit side of the display panel 300, and a side facing away from the light-exit side of the display panel 300 is a non-light-exit side of the display panel 300.

For example, the display panel 300 may be an organic light-emitting diode (OLED) display panel, a quantum dot light-emitting diode (QLED) display panel, a micro light-emitting diode (Micro LED) display panel, or a mini light-emitting diode (Mini LED) display panel, which is not specifically limited in the present disclosure.

Some embodiments of the present disclosure will be schematically described below by taking an example in which the display panel 300 is an OLED display panel.

In some examples, as shown in FIGS. 2 and 3, the display panel 300 includes: a substrate 10, a driving circuit layer 20, a plurality of pixel electrodes 301, a pixel definition structure 40, and a plurality light-emitting portions 302.

A type of substrate 10 varies, which can be determined according to actual needs.

For example, the substrate 10 may be a rigid substrate. The rigid substrate may be a glass substrate or a polymethyl methacrylate (PMMA) substrate.

For another example, the substrate 10 may be a flexible substrate. The flexible substrate may be a polyethylene terephthalate (PET) substrate, a polyethylene naphthalate (PEN) substrate, or a polyimide (PI) substrate. In this case, the display panel 300 may realize flexible display, for example.

Optionally, the substrate 10 may be of a single-layer structure, a double-layer structure or a multi-layer structure. The embodiments of the present disclosure are not limited thereto.

Referring to FIGS. 2 and 3, the driving circuit layer 20 is disposed on the substrate 10. It will be understood that the driving circuit layer 20 refers to a film layer where a plurality of pixel circuit arrays are located, including a plurality of patterned conductive layers and insulating layers. For example, the driving circuit layer 20 includes a plurality of pixel circuits 210, a plurality of signal lines, and other structures.

The pixel circuit 210 is generally composed of electronic devices such as a thin film transistor (TFT) and a capacitor. For example, the pixel circuit 210 may have a “2T1C” structure, a “6T1C” structure, a “7T1C” structure, a “6T2C” structure, a “7T2C” structure, or the like. Here, “T” represents a transistor, e.g., a thin film transistor; a number preceding “T” represents the number of transistors; “C” represents a capacitor; and a number preceding “C” represents the number of capacitors. In accompany drawings of some embodiments of the present disclosure, only one thin film transistor 211 is taken as an example for illustration. For example, the thin film transistor 211 may be a driving transistor.

As shown in FIG. 2, the driving circuit layer 20 may include a semiconductor layer 201, a first gate insulating layer 202, a gate metal layer 203, a second gate insulating layer 204, and a source-drain metal layer 205. The semiconductor layer 201 includes active layers of the plurality of thin film transistors 211. The gate metal layer 203 includes gates of the plurality of thin film transistors 211. The source-drain metal layer 205 includes sources and drains of the plurality of thin film transistors 211.

It can be understood that the thin film transistors included in the driving circuit layer 20 may be top-gate thin film transistors or bottom-gate thin film transistors, which will not be limited in the embodiments of the present disclosure. The thin film transistor 211 shown in FIG. 2 may be a top-gate thin film transistor.

As shown in FIGS. 2 and 3, the pixel electrodes 301 are disposed on a side of the driving circuit layer 20 away from the substrate 10. The pixel electrode 301 is connected to the pixel circuit 210 in the driving circuit layer 20, to receive an electrical signal provided by the pixel circuit 210.

A material of the pixel electrode 301 may include metal and alloy, such as aluminum (Al), magnesium (Mg) and silver (Ag); or it may include metal oxide, such as indium tin oxide (ITO) and indium zinc oxide (IZO).

As shown in FIGS. 2 and 3, the pixel definition structure 40 is disposed on a side of the plurality of pixel electrodes 301 away from the driving circuit layer 20, and the pixel definition structure 40 is provided therein with a plurality of pixel openings 401. One pixel opening 401 corresponds to one pixel electrode 301, and one pixel opening 401 exposes at least part of one pixel electrode 301. For example, a surface of the pixel electrode 301 away from the substrate 10 may be fully exposed by the pixel opening 401, or may be partially exposed and partially covered by the pixel definition structure 40. The embodiments of the present disclosure are not limited thereto.

A type of the pixel definition structure 40 varies, which can be set according to actual needs.

In some examples, as shown in FIG. 2, the pixel definition structure 40 includes a pixel definition layer 41. The pixel definition layer 41 defines the plurality of pixel openings 401. The top view structure of the pixel definition layer 41 is similar to a grid, and the plurality of pixel openings 401 constitute meshes of the grid.

For example, a material used for the pixel definition layer 41 may include at least one of an inorganic insulating material and an organic insulating material, such as silicon nitride (SiNx), silicon oxynitride (SiON), and silicon oxide (SiOx).

In some other examples, as shown in FIG. 3, the pixel definition structure 40 includes a pixel definition layer 41 and an isolation structure 42 located on a side of the pixel definition layer 41 away from the plurality of pixel electrodes 301. An orthographic projection of the isolation structure 42 on the substrate 10 is located within an orthographic projection of the pixel definition layer 41 on the substrate 10.

For example, as shown in FIG. 3, the pixel definition layer 41 has a plurality of first openings 411, and one first opening 411 exposes at least part of one pixel electrode 301. As for the material of the pixel definition layer 41, reference can be made to the description in the above examples. The isolation structure 42 has a plurality of second openings 421. One first opening 411 corresponds to one second opening 421, and an orthogonal projection of the first opening 411 on the substrate 10 is located within an orthogonal projection of the second opening 421 on the substrate 10.

For example, the isolation structure 42 may be a stacked structure of metal materials, the metal materials may be pure metal materials or metal compounds. The metal materials include titanium (Ti), aluminum (Al), molybdenum (Mo) or other ferrous metals. For example, the isolation structure 42 may be a stacked structure of Ti/Al/Ti, where the wet etching rates of Ti and Al are different, so that an undercut structure (e.g., a structure in a shape of the Chinese character “ [symbol] ”) may be formed. The isolation structure 42 may also be a stacked structure of Mo/Al/Mo. The embodiments of the present disclosure are not limited thereto.

The isolation structure 42 may also be a stacked structure of a metal material and a black organic material, where the organic material includes a black resin adhesive. The metal material may include a ferrous metal material, such as MoOx.

It will be noted that the isolation structure 42 may be a three-layer structure (the structure in a shape of the Chinese character “ [symbol] ”) shown in FIG. 3, or may be a two-layer structure or a four-layer structure, or may be a structure of more layers, which is not specifically limited here, as long as the isolation structure 42 has an undercut structure.

It will be noted that, in a case where the pixel definition structure 40 includes the pixel definition layer 41 and the isolation structure 42, the pixel openings 401 included in the pixel definition structure 40 can be understood as the first openings 411 provided in the pixel definition layer 41.

As shown in FIGS. 2 and 3, one light-emitting portion 302 is disposed in one pixel opening 401.

In some examples, the light-emitting portion 302 includes an electroluminescent (EL) layer.

In some other examples, the light-emitting portion 302 includes the EL layer, and further includes one or more of an electron transport layer (ETL), an electron injection layer (EIL), a hole blocking layer (HBL), a hole transport layer (HTL), an electron blocking layer (EBL), and a hole injection layer (HIL). In a case where the display panel 300 is an organic electroluminescence display panel, the EL layer is an organic EL layer. In a case where the display panel 300 is a quantum dot electroluminescence display panel, the EL layer is a quantum dot EL layer.

As shown in FIGS. 2 and 3, the display panel 300 further includes: a plurality of common electrodes 303 disposed on a side of the light-emitting portions 302 away from the pixel electrodes 301. A material used for the common electrodes 303 may include a (semi) transparent layer including at least one or more of silver (Ag), magnesium (Mg), aluminum (Al), platinum (Pt), gold (Au), nickel (Ni), chromium (Cr) and lithium (Li). For example, the material used for the common electrodes 303 includes Ti/Al/Ti metals stacked to form a multi-layer structure.

In some examples, the plurality of common electrodes 303 are connected to each other to constitute a common electrode layer.

In some other examples, the plurality of common electrodes 303 are separated from each other. For example, in a case where the pixel definition structure 40 includes the pixel definition layer 41 and the isolation structure 42, the isolation structure 42 may separate any two common electrodes 303, that is, two adjacent common electrodes 303 are spaced apart and not directly connected. However, two adjacent common electrodes 303 may be electrically connected. For example, two adjacent common electrodes 303 are electrically connected via the isolation structure 42. Therefore, it may ensure that the light-emitting portions 302 in the pixel openings 401 may receive approximately the same electrical signals transmitted by the common electrodes 303, which is conducive to improving the accuracy of the electrical signals received by the plurality of light-emitting portions 302 and in turn improving the display uniformity of the display panel 300.

It can be understood that overlapping portions of the pixel electrode 301, the light-emitting portion 302, and the common electrode 303 form a light-emitting device 30. Optionally, the pixel electrode 301 is an anode of the light-emitting device 30, and the common electrode 303 is a cathode of the light-emitting device 30. Voltages are applied to the pixel electrode 301 and the common electrode 303, an electric field is created between the pixel electrode 301 and the common electrode 303, which can drive holes in the pixel electrode 301 and electrons in the common electrode 303 to recombine in the light-emitting portion 302, thereby emitting light.

The pixel electrode 301 of the light-emitting device 30 is electrically connected to the pixel circuit 210. The pixel circuit 210 is capable of generating a driving signal and transmitting the driving signal to the corresponding light-emitting device 30, so as to control a light-emitting state of the light-emitting device 30. The light-emitting state includes, for example, whether the light-emitting device 30 emits light, or the light-emitting brightness of the light-emitting device 30. The plurality of pixel circuits 210 together control light-emitting states of the plurality of light-emitting devices 30, thereby enabling the display panel 300 to display images.

In some examples, as shown in FIG. 2, at least one insulating dielectric layer 50 is provided between the pixel electrodes 301 and the driving circuit layer 20. A material used for the insulating dielectric layer 50 may include an organic insulating material, or inorganic and organic insulating materials. For example, the organic insulating material includes at least one of: general-purpose polymers such as polymethyl methacrylate (PMMA) and polystyrene (PS), polymer derivatives with phenol-based groups, acryl-based polymers, imide-based polymers, aryl ether-based polymers, amide-based polymers, fluorine-based polymers, p-xylene-based polymers, or vinyl alcohol-based polymers. For example, the material used for the insulating dielectric layer 50 includes polyimide.

As shown in FIG. 2, the insulating dielectric layer 50 is provided therein with via holes 501. The pixel electrodes 301 are electrically connected to the driving circuit layer 20 through the via holes 501.

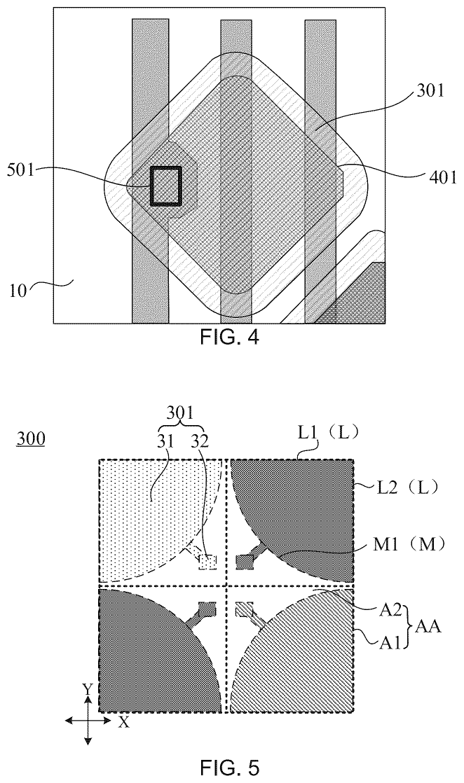

In an implementation, in order to meet the requirement of high pixel per inch (PPI) of the display panel 300, a distance between two adjacent pixel openings 401 is set very small, and the via hole 501 can only be arranged in a region of the pixel opening. For example, referring to FIGS. 2 and 4, an orthogonal projection of the via hole 501 on the substrate 10 is located within an orthogonal projection of the pixel opening 401 on the substrate 10; an orthogonal projection, on the substrate 10, of a portion of the pixel electrode 301 used for being connected to the pixel circuit 210 is located within the orthogonal projection, on the substrate 10, of the pixel opening 401; and the portion of the pixel electrode 301 is electrically connected to the pixel circuit 210 through the via hole 501.

Those skilled in the art will understand that the light-emitting device 30 has high requirements on the flatness of the surface on which the light-emitting device 30 is disposed. The flatter the surface on which the light-emitting device 30 is disposed, the better the light-emitting quality of the light-emitting device 30. If the surface on which the light-emitting device 30 is disposed is uneven, the light-emitting quality of the light-emitting device 30 will be greatly affected.

In the embodiments shown in FIGS. 2 to 4, since the orthogonal projection of the via hole 501 on the substrate 10 is located within the orthogonal projection of the pixel opening 401 on the substrate 10, there is a step difference in a surface of the pixel electrode 301 in contact with the light-emitting portion 302 (that is, a surface of a portion of the pixel electrode 301 exposed by the pixel opening 401). Therefore, there is a step difference in the light-emitting portion 302. As a result, a light-emitting surface of the light-emitting device 30 is not on the same surface, and light exit angles at different positions of the light-emitting device 30 are different, which seriously affects the light-emitting quality of the light-emitting device 30. Thus, the color of the light-emitting device 30 observed by the observer has color deviation, which affects the display effect of the display panel 300.

In some other implementations, in order to solve the problem of difficulty in aligning the display panel to be evaporated and a fine metal mask (FMM) and difficulty in fabrication when forming the light-emitting layer by using the FMM for whole-layer evaporation, the light-emitting portions 302 and the common electrodes 303 are fabricated using a photolithography process.

The above-mentioned “photolithography process” may include: after forming the whole-layer light-emitting layer and the whole-layer common electrode layer, coating the common electrode layer with a photoresist; then providing a mask on a side of the photoresist away from the substrate, and exposing and developing the photoresist through the mask to remove an exposed part of the photoresist and retain an unexposed part of the photoresist, so that a patterned photoresist is formed; then etching the light-emitting layer and the common electrode layer using the patterned photoresist as a mask, to remove a part of the light-emitting layer and a part of the common electrode layer that are not blocked by the patterned photoresist, so that the plurality of light-emitting portions 302 and the common electrodes 303 are obtained. Then, the display panel 300 to be formed may be placed in a stripping solution to dissolve and strip off the patterned photoresist.

In the case where the orthogonal projection of the via hole 501 on the substrate 10 is located within the orthogonal projection of the pixel opening 401 on the substrate 10, when a part of the light-emitting layer and a part of the common electrode layer are located in the via hole 501, during the process of forming the light-emitting portions 302 and the common electrodes 303 using the photolithography process, the part of the light-emitting layer and the part of the common electrode layer located in the via hole 501 is prone to insufficient etching, resulting in residual film layers of the light-emitting layer and the common electrode layer in the via hole 501, which causes growing dark spot (GDS) defects in the display panel 300 and affects the display effect of the display panel 300.

In light of this, in the embodiments of the present disclosure, further improvements have been made to the display panel 300. As shown in FIG. 5, FIG. 5 is a structural diagram of a display panel 300 provided in some embodiments of the present disclosure.

As shown in FIG. 5, the display panel 300 includes a plurality of rectangular sub-pixel regions AA; each sub-pixel region AA includes a light-emitting region A1 and an avoidance region A2 that are adjacent and connected to each other; the avoidance region A2 includes a vertex corner of a rectangle; and a region of the rectangle other than the avoidance region A2 is the light-emitting region A1.

A sub-pixel region AA is provided therein with a sub-pixel. A plurality of sub-pixels are arranged in a plurality of rows and a plurality of columns, sub-pixels in each row are arranged in an X direction, and sub-pixels in each column are arranged in a Y direction. The sub-pixel is the smallest unit for displaying images in the display panel 300. Each sub-pixel may display a single color, such as red, blue or green. By adjusting the luminance (gray scales) of sub-pixels of different colors, multiple colors may be displayed due to color combination and superposition, thereby realizing full-color display of the display panel 300.

A sub-pixel includes a pixel circuit and a light-emitting device. In a sub-pixel, the light-emitting device 30 is located in the light-emitting region A1.

Shapes of the light-emitting region A1 and the avoidance region A2 vary, which may be set according to actual needs.

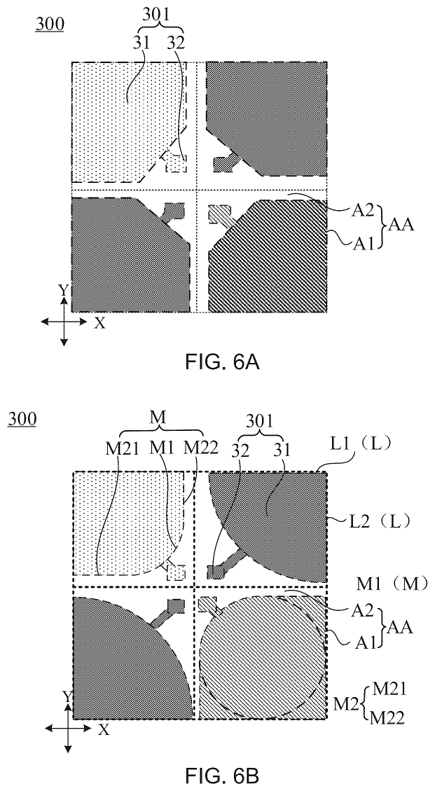

In some examples, as shown in FIG. 6A, the shape of the light-emitting region A1 may be a pentagon which is formed by cutting off a vertex corner of a rectangle, a trapezoid, or other regular polygons.

In a case where the shape of the light-emitting region A1 is a regular polygon, the shape of the avoidance region A2 is also a regular polygon. For example, as shown in FIG. 6A, when the shape of the light-emitting region A1 is a pentagon, the shape of the avoidance region A2 may be a triangle.

In some other examples, the light-emitting region A1 may be a special-shaped light-emitting region. The shape of the special-shaped light-emitting region may vary, which is not limited in the embodiments of the present disclosure.

It will be noted that the “special-shaped light-emitting region” is only used to distinguish it from light-emitting regions of other shapes (e.g., a trapezoidal light-emitting region). The shape of the “special-shaped light-emitting region” may be an irregular enclosed shape consisting of curved segment(s) and straight segment(s), or may be an irregular shape consisting of a plurality of straight segments. For example, as shown in FIG. 5, the special-shaped light-emitting region A1 is an irregular enclosed shape consisting of two perpendicular edges and one arc edge.

In addition, when the light-emitting region A1 is a special-shaped light-emitting region, the avoidance region A2 is a special-shaped avoidance region. The special-shaped avoidance region and the special-shaped light-emitting region cooperate with each other to constitute a rectangular sub-pixel region AA.

The pixel opening 401 of the pixel definition structure 40 is disposed in the light-emitting region A1, and the shape of the pixel opening 401 is the same as the shape of the light-emitting region A1. For example, the shape of the light-emitting region A1 and the shape of the pixel opening 401 are both regular polygons (e.g., pentagons). For another example, the light-emitting region A1 and the pixel opening 401 are special-shaped (e.g., fan-shaped).

As shown in FIG. 5, the pixel electrode 301 includes a main body 31 and a connection portion 32 that are connected to each other. A shape of the main body 31 is the same as the shape of the pixel opening 401. The connection portion 32 is located in the avoidance region A2, and the connection portion 32 is connected to the driving circuit layer 20.

For example, when the shape of the pixel opening 401 is a regular polygon (e.g., a pentagon), the shape of the main body 31 is also a regular polygon (e.g., a pentagon); and when the pixel opening 401 is special-shaped (e.g., fan-shaped), the main body 31 is also special-shaped (e.g., fan-shaped). The embodiments of the present disclosure are not limited thereto.

For example, a thickness of the main body 31 is uniform with no step difference, and the connection portion 32 has a fault.

The thickness of the main body 31 is uniform with no step difference, which means that a side surface of the main body 31 close to the substrate 10 and a side surface of the main body 31 away from the substrate 10 are both on the same horizontal plane. The connection portion 32 has a fault, which means that a side surface of the connection portion 32 close to the substrate 10 is not on the same horizontal plane, and a side surface of the connection portion 32 away from the substrate 10 is not on the same horizontal plane.

For example, an end of the connection portion 32 is electrically connected to the main body 31, and another end of the connection portion 32 is electrically connected to the pixel circuit 210 in the driving circuit layer 20, thereby realizing an electrical connection between the light-emitting device 30 and the pixel circuit 210. Therefore, the driving signal generated by the pixel circuit 210 can be transmitted to the corresponding light-emitting device 30, to control the light-emitting state of the light-emitting device 30.

In the above-mentioned display panel 300, a vertex corner of the rectangular sub-pixel region AA is set as the avoidance region A2, and the connection portion 32 of the pixel electrode 301 for being connected to the driving circuit layer 20 is disposed in the avoidance region A2. Therefore, it is possible to ameliorate the problem that the connection portion 32 is disposed in the light-emitting region A1, causing a region of the pixel electrode 301 overlapping with the light-emitting portion 302 and the light-emitting portion 302 to be uneven, resulting in a phenomenon that the light-emitting surface of the light-emitting device 30 is not on the same surface, the light exit angles at different positions are different, and the color of the light-emitting device 30 observed by the observer has color deviation. Thus, the display effect of the display panel 300 is improved.

In addition, the connection portion 32 of the pixel electrode 301 is disposed in the avoidance region A2, so that a surface of the portion of the pixel electrode 301 exposed by the pixel opening 401 is flat, which facilitates the subsequent fabrication of structures such as the light-emitting portions 302 and the common electrodes 303, and avoids a situation where the light-emitting layer and the common electrode layer are not fully etched and the film layers remain due to the step difference in the surface of the portion of the pixel electrode 301 exposed by the pixel opening 401 when the structures such as the light-emitting portions 302 and the common electrodes 303 are formed by the photolithography process. Thus, the yield of the display panel 300 is improved.

In some embodiments, as shown in FIG. 5, a boundary of the main body 31 includes two perpendicular edges L and a set edge M that are connected; ends of the two perpendicular edges L are connected and form a right angle, and two ends of the two perpendicular edges L that are far away from each other are respectively connected to two ends of the set edge M; and the set edge M includes an arc segment M1. An end of the connection portion 32 is connected to the arc segment M1 of the boundary of the main body 31, and another end of the connection portion 32 extends in a direction away from the main body 31 and is connected to the driving circuit layer 20.

For example, as shown in FIG. 5, the two perpendicular edges L are respectively a first edge L1 and a second edge L2. The first edge L1 is parallel to a row direction X in which the plurality of sub-pixels included in a pixel arrangement structure are arranged, and the second edge L2 is parallel to a column direction Y in which the plurality of sub-pixels included in the pixel arrangement structure are arranged. An end of the first edge L1 is connected to an end of the set edge M, and the second edge L2 is connected to another end of the set edge M. An end of the first edge L1 away from the set edge M is connected to an end of the second edge L2 away from the set edge M, so that the first edge L1, the second edge L2 and the set edge M can form an enclosed pattern. The first edge L1 and the second edge L2 intersect to form a right angle.

In addition, the arc segment M1 included in the set edge M may be bent toward the above right angle, or may be bent away from the above right angle, which will not be limited in the embodiments of the present disclosure. For example, the arc segment M1 is bent away from the above right angle, as shown in FIG. 5. Therefore, by setting a vertex corner of the rectangular sub-pixel region AA as the avoidance region A2 and setting the connection portion 32 of the pixel electrode 301 for being connected to the driving circuit layer 20 in the avoidance region A2, the main body 31 of the pixel electrode 301 located at the pixel opening 401 is flat and has no step difference, and the light-emitting portion 302 is flat and has no step difference, which ensures the light-emitting quality of the light-emitting device 30, and may ensure a large area of the light-emitting region A1 of the light-emitting device 30, which in turn ensures the aperture ratio of the display panel 300.

It can be understood that a size of the rectangular sub-pixel region AA can be adjusted by setting lengths of the first edge L1 and the second edge L2.

Furthermore, the lengths of the first edge L1 and the second edge L2 may be the same or different, which will not be limited in the embodiments of the present disclosure. For example, as shown in FIG. 5, the lengths of the first edge L1 and the second edge L2 are the same, thereby improving the regularity of the plurality of pixel electrodes 301.

It can be seen from the above that the shape of the light-emitting region A1 is the same as the shape of the main body 31. In the case where the boundary of the main body 31 includes the two perpendicular edges L and the set edge M that are connected, a boundary of the light-emitting region A1 includes two perpendicular edges of the rectangular sub-pixel region AA and a side edge that substantially coincides with the set edge M of the main body 31. An enclosed region formed by the side edge and other two perpendicular edges of the rectangular sub-pixel region AA constitutes the avoidance region A2.

In this embodiment, based on the above-mentioned arrangement, the shape of the main body 31 is defined, that is, the shape of the light-emitting region A1 is defined. The boundary of the light-emitting region A1 includes two perpendicular edges of the rectangular sub-pixel region AA and a side edge that substantially coincides with the set edge M of the main body 31, and the avoidance region A2 includes a vertex corner of the rectangular sub-pixel region AA. By arranging the connection portion 32 of the pixel electrode 301 in the avoidance region A2, it is possible to ameliorate the problem that the connection portion 32 is disposed in the light-emitting region A1, causing a region of the pixel electrode 301 overlapping with the light-emitting portion 302 and the light-emitting portion 302 to be uneven, resulting in a phenomenon that the light-emitting surface of the light-emitting device 30 is not on the same surface, the light exit angles at different positions are different, and the color of the light-emitting device 30 observed by the observer has color deviation. Thus, the display effect of the display panel 300 is improved.

It will be noted that, the arrangement manner of the set edge M varies, which may be selected according to actual needs.

In an implementation, as shown in FIG. 5, the set edge M only includes the arc segment M1. Two ends of the arc segment M1 are respectively connected to two ends, far away from each other, of the two perpendicular edges L.

For example, an end of the first edge L1 is connected to an end of the arc segment M1, the second edge L2 is connected to another end of the arc segment M1, and an end of the first edge L1 away from the arc segment M1 is connected to an end of the second edge L2 away from the arc segment M1, so that the first edge L1, the second edge L2 and the arc segment M1 can form an enclosed pattern.

The shape of the light-emitting region A1 is the same as the shape of the main body 31. In the case where the boundary of the main body 31 includes the two perpendicular edges L and the arc segment M1 that are connected, the boundary of the light-emitting region A1 includes two perpendicular edges of the rectangular sub-pixel region AA and a side edge that substantially coincides with the arc segment M1. An enclosed region formed by the side edge and other two perpendicular edges of the rectangular sub-pixel region AA constitutes the avoidance region A2.

In this way, the shape of the main body 31 is defined, that is, the shape of the light-emitting region A1 is defined. The boundary of the light-emitting region A1 includes two perpendicular edges of the rectangular sub-pixel region AA and a side edge that substantially coincides with the arc segment M1, and the avoidance region A2 includes a vertex corner of the rectangular sub-pixel region AA. By arranging the connection portion 32 of the pixel electrode 301 in the avoidance region A2, it is possible to ameliorate the problem that the connection portion 32 is disposed in the light-emitting region A1, causing a region of the pixel electrode 301 overlapping with the light-emitting portion 302 and the light-emitting portion 302 to be uneven, resulting in a phenomenon that the light-emitting surface of the light-emitting device 30 is not on the same surface, the light exit angles at different positions are different, and the color of the light-emitting device 30 observed by the observer has color deviation. Thus, the display effect of the display panel 300 is improved.

In addition, the boundary of the light-emitting region A1 includes two perpendicular edges of the rectangular sub-pixel region AA and a side edge that substantially coincides with the arc segment M1, and the arc segment M1 is smooth, which weakens the visual prominence of the boundary of the light-emitting region A1 and reduces a jaggy feeling at the arc segment, so that the display effect of the display panel 300 is further improved.

In another implementation, as shown in FIG. 6B, the set edge M further includes two straight segments M2, and the two straight segments M2 are respectively located on two ends of the arc segment M1. A straight segment M2 is connected to an end of the arc segment M1 and an end of a perpendicular edge L.

For example, as shown in FIG. 6B, the two straight segments M2 are respectively a first straight segment M21 and a second straight segment M22. The first straight segment M21 is parallel to the row direction X in which the plurality of sub-pixels included in the pixel arrangement structure are arranged, and the second straight segment M22 is parallel to the column direction Y in which the plurality of sub-pixels included in the pixel arrangement structure are arranged.

For example, an end of the first straight segment M21 is connected to an end of the arc segment M1, and the second straight segment M22 is connected to another end of the arc segment M1. An end of the first straight segment M21 away from the arc segment M1 is connected to an end of the second edge L2 away from the first edge L1, and an end of the second straight segment M22 away from the arc segment M1 is connected to an end of the first edge L1 away from the second edge L2. Therefore, the first edge L1, the second edge L2, the first straight segment M21, the second straight segment M22 and the arc segment M1 can form an enclosed pattern. The first straight segment M21 and the second edge L2 intersect to form a right angle. The second straight segment M22 and the first edge L1 intersect to form a right angle.

Moreover, lengths of the first straight segment M21 and the second straight segment M22 may be the same or different, which will not be limited in the embodiments of the present disclosure. For example, as shown in FIG. 6B, the lengths of the first straight segment M21 and the second straight segment M22 are the same, thereby improving the regularity of the pixel electrodes 301 and facilitating the fabrication of the pixel electrodes 302.

It can be understood that, when the lengths of the first edge L1 and the second edge L2 of the main body 31 are constant, when the lengths of the straight segments M2 in the set edge M change, an area of the main body 31 also changes accordingly. For example, when the lengths of the first edge L1 and the second edge L2 of the main body 31 are constant, the greater the lengths of the straight segments M2, the larger the area of the main body 31; and the smaller the lengths of the straight segments M2, the smaller the area of the main body 31.

It can be seen from the above that the light-emitting region A1 and the main body 31 have the same shape and areas thereof are approximately the same. In the case where the set edge M further includes the two straight segments M2, the area of the main body 31 is large, that is, the area of the light-emitting region A1 is large. Moreover, by setting the lengths of the straight segments M2, the area of the light-emitting region A1 may be increased as much as possible, thereby increasing the aperture ratio of the display panel 300.

In addition, in the case where the set edge M included in the boundary of the main body 31 further includes the two straight segments M2, the boundary of the light-emitting region A1 includes two perpendicular edges of the rectangular sub-pixel region AA and a side edge that substantially coincides with the set edge M, and the side edge also includes two straight segments and an arc segment.

In this way, the shape of the main body 31 is defined, that is, the shape of the light-emitting region A1 is defined. A vertex corner of the rectangular sub-pixel region AA is set as the avoidance region A2, and the connection portion 32 of the pixel electrode 301 is arranged in the avoidance region A2. Therefore, it is possible to ameliorate the problem that the connection portion 32 is disposed in the light-emitting region A1, causing a region of the pixel electrode 301 overlapping with the light-emitting portion 302 and the light-emitting portion 302 to be uneven, resulting in a phenomenon that the light-emitting surface of the light-emitting device 30 is not on the same surface, the light exit angles at different positions are different, and the color of the light-emitting device 30 observed by the observer has color deviation. Thus, the display effect of the display panel 300 is improved.

In addition, by adjusting the lengths of the straight segments M2 and the arc segment M1 of the set edge M, the area of the main body 31 can be adjusted. The shape of the light-emitting region A1 is the same as the shape of the main body 31, and the area of the light-emitting region A1 is approximately the same as the area of the main body 31. That is, the area of the light-emitting region A1 may be set according to needs.

In some embodiments, a radius of curvature of the arc segment M1 is less than or equal to a size of the perpendicular edge L.

For example, as shown in FIG. 5, the radius of curvature of the arc segment M1 is equal to the size of the perpendicular edge L. In this case, a center of the arc segment M1 coincides with an intersection of the two perpendicular edges L.

For another example, as shown in FIG. 6B, the radius of curvature of the arc segment M1 is less than the size of the perpendicular edge L. For example, the radius of curvature of the arc segment M1 is equal to half the size of the perpendicular edge L. In this case, the center of the arc segment M1 is located inside the right angle formed by the two perpendicular edges L intersecting.

As shown in FIGS. 5 and 6B, in a case where the sizes of the two perpendicular edges of the light-emitting region A1 are constant, if the radius of curvature of the arc segment M1 varies, an area of the orthographic projection of the main body 31 on the substrate 10 also varies. That is, the area of the main body 31 can be set by setting the radius of curvature of the arc segment M1.

It can be seen from the above that, the shape of the light-emitting region A1 is the same as the shape of the main body 31, and the area of the light-emitting region A1 is approximately the same as the area of the main body 31. In this embodiment, by setting the radius of curvature of the arc segment M1, the area of the main body 31 can be set, that is, the area of the light-emitting region A1 can be set. Therefore, the area of the light-emitting region A1 is adjustable. That is, the area of the light-emitting region A1 can be set according to actual needs. For example, the area of the light-emitting region A1 is set to be large, so that the aperture ratio of the display panel 300 is increased and the service life of the display panel 300 is increased.

In some embodiments, the orthographic projection of the main body 31 on the substrate 10 is fan-shaped or approximately fan-shaped, or is in a shape of a polygon obtained by cutting off a corner of a rectangle.

The “approximately fan-shaped” means that the orthographic projection of the main body 31 on the substrate 10 is in a shape of a fan as a whole, but is not limited to a standard fan. For example, as shown in FIG. 6B, in the case where the set edge M of the main body 31 includes the arc segment M1 and the two straight segments M2 that are respectively located on two ends of the arc segment M1, the orthographic projection of the main body 31 on the substrate 10 is approximately fan-shaped.

It can be seen from the above that the shape of the light-emitting region A1 is the same as the shape of the main body 31. For example, in the case where the orthographic projection of the main body 31 on the substrate 10 is fan-shaped, the light-emitting region A1 is fan-shaped. For another example, in the case where the shape of the orthographic projection of the main body 31 on the substrate 10 is a polygon obtained by cutting off a corner of a rectangle, the shape of the light-emitting region A1 is a polygon obtained by cutting off a corner of a rectangle.

In this embodiment, the shape of the main body 31 is defined, that is, the shape of the light-emitting region A1 is defined. The shape of the light-emitting region A1 is a fan shape, approximately a fan shape, or a polygon formed by cutting off a vertex corner of a rectangle, the avoidance region A2 includes a vertex corner of the rectangular sub-pixel region AA, and the connection portion 32 of the pixel electrode 301 is arranged in the avoidance region A2. Therefore, it is possible to ameliorate the problem that the connection portion 32 is disposed in the light-emitting region A1, causing a region of the pixel electrode 301 overlapping with the light-emitting portion 302 and the light-emitting portion 302 to be uneven, resulting in a phenomenon that the light-emitting surface of the light-emitting device 30 is not on the same surface, the light exit angles at different positions are different, and the color of the light-emitting device 30 observed by the observer has color deviation. Thus, the display effect of the display panel 300 is improved.

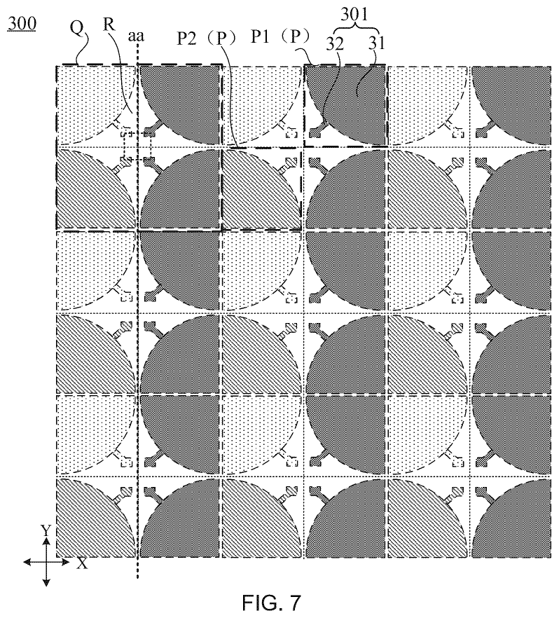

In some embodiments, as shown in FIG. 7, the display panel 300 includes a plurality of pixel units Q; each pixel unit Q includes four sub-pixels P; the four sub-pixels P are arranged in a 2×2 matrix; and each sub-pixel P includes a pixel electrode 301 and a light-emitting portion 302 (not shown in the figure) corresponding to the pixel electrode 301. Set edges M of main bodies 31 of pixel electrodes 301 of the four sub-pixels P are close to each other and enclose an accommodation region R. Connection portions 32 of the pixel electrodes 301 of the four sub-pixels P are close to each other and are located in the accommodation region R.

For example, one sub-pixel region AA is provided therein with one sub-pixel P, and each pixel unit Q includes four sub-pixels P. That is, a region where each pixel unit Q is located consists of four sub-pixel regions AA. The shape of the sub-pixel region AA is rectangular, and the four sub-pixel regions AA included in the region of each pixel unit are arranged in a 2×2 matrix to form a square. Thus, it may ensure a more compact arrangement of the plurality of pixel units Q, which improves the space utilization of the display panel 300 and facilitates the improvement of the PPI of the display panel 300.

For example, as shown in FIG. 6B, the plurality of pixel units Q are arranged in a plurality of rows and a plurality of columns; pixel units Q in each row are arranged in the X direction; and pixel units Q in each column are arranged in the Y direction.

It will be noted that each sub-pixel P further includes a common electrode 303. A pixel electrode 301, a light-emitting portion 302 corresponding to the pixel electrode 301, and a common electrode 303 together form a light-emitting device 30.

The four sub-pixels P included in each pixel unit Q include at least red sub-pixel(s), blue sub-pixel(s), and green sub-pixel(s). For example, a light-emitting device 30 in the red sub-pixel is configured to emit red light, a light-emitting device 30 in the blue sub-pixel is configured to emit blue light, and a light-emitting device 30 in the green sub-pixel is configured to emit green light. In some other examples, the light-emitting devices 30 in the red sub-pixel, the green sub-pixel, and the blue sub-pixel are each configured to emit white light; in this case, the display panel 300 may further include a red filter located in the red sub-pixel, a green filter located in the green sub-pixel, and a blue filter located in the blue sub-pixel. The embodiments of the present disclosure are not limited thereto.

It can be understood that any two light-emitting devices 30 are separated by the pixel definition structure 40. Each sub-pixel region AA includes a light-emitting region A1 and an avoidance region A2 that are adjacent and connected to each other; the light-emitting device 30 is located in the light-emitting region A1; and a portion of the pixel definition structure 40 is located in the avoidance region A2. In the case where the set edges M of the main bodies 31 of the pixel electrodes 302 of the four sub-pixels P included in each pixel unit Q are close to each other and enclose an accommodation region R, portions the pixel definition structure 40 between the light-emitting devices 30 in the four sub-pixels P are connected to form a one-piece structure, and are located in the accommodation region R.

In this way, the connection portion 32 of the pixel electrode 301 is disposed in the avoidance region A2, so as to ameliorate the problem that the connection portion 32 is disposed in the light-emitting region A1, causing a region of the pixel electrode 301 overlapping with the light-emitting portion 302 and the light-emitting portion 302 to be uneven, resulting in a phenomenon that the light-emitting surface of the light-emitting device 30 is not on the same surface, the light exit angles at different positions are different, and the color of the light-emitting device 30 observed by the observer has color deviation. Moreover, portions the pixel definition structure 40 between the light-emitting devices 30 in the four sub-pixels P included in each pixel unit Q are connected to form a one-piece structure. When forming the pixel definition structure 40, the portions the pixel definition structure 40 between the light-emitting devices 30 in the four sub-pixels P correspond to one opening of a mask, thereby reducing the accuracy requirements on the mask.

In some embodiments, as shown in FIG. 7, a shape formed by a line connecting an end of each of the connection portions 32 of the four sub-pixels P that is away from a respective main body 31 is a square.

For example, as shown in FIG. 7, in one pixel unit Q, a line connecting an end, away from a respective main body 31, of each of connection portions 32 of two sub-pixels P that are arranged in the X direction and located in the same row is parallel to the X direction; and a line connecting an end, away from a respective main body 31, of each of connection portions 32 in two sub-pixels P that are arranged in the Y direction and located in the same column is parallel to the Y direction.

For example, as shown in FIG. 7, connection portions 32 of two sub-pixels P that are located in the same row in one pixel unit Q are symmetrically arranged with respect to a bisector that is perpendicular to the row direction X in which the plurality of sub-pixels are arranged and is located between the two sub-pixels P.

For example, as shown in FIG. 7, connection portions 32 of two sub-pixels P that are located in the same column in one pixel unit Q are symmetrically arranged with respect to a bisector that is perpendicular to the column direction Y in which the plurality of sub-pixels are arranged and is located between the two sub-pixels P.

Therefore, the connection portions 32 of the four sub-pixels P are evenly distributed in one pixel unit Q, so that loads on the pixel electrodes 301 are approximately the same, which is conducive to reducing differences in signals received by the pixel electrodes 301 and improving the display uniformity of the display panel 300.

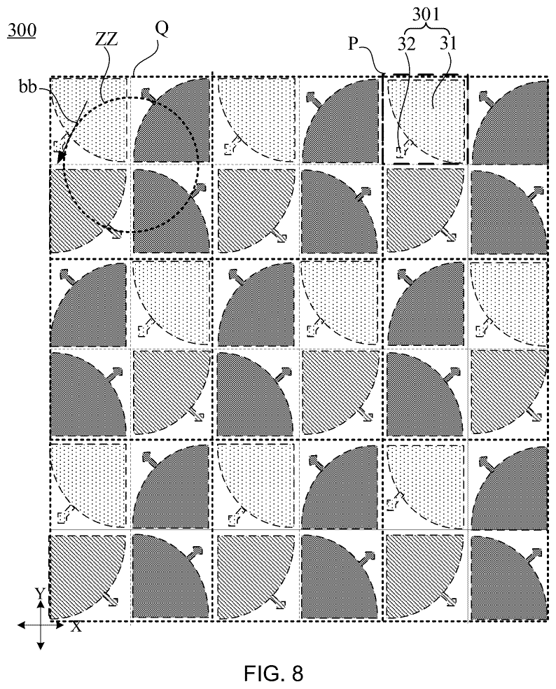

In some other embodiments, as shown in FIG. 8, along a circumferential direction ZZ around a center of the pixel unit Q, the main bodies 31 and the connection portions 32 of the four pixel electrodes 301 of the four sub-pixels P are arranged alternately.

For example, as shown in FIG. 8, the main bodies 31 of the four pixel electrodes 301 of the four sub-pixels P are distributed in a windmill shape. For example, among the main bodies 31 of two adjacent pixel electrodes 301, the main body 31 of one pixel electrode 301 rotates 90° in the same direction (e.g., clockwise) around the center of the pixel unit Q, and then overlaps with the main body 31 of another pixel electrode 301.

In some embodiments, as shown in FIG. 8, the connection portion 32 extends along a tangent direction bb of the circumferential direction ZZ around the center of the pixel unit Q.

For example, as shown in FIG. 8, the set edge M of the main body 31 overlaps with a circle around the center of the pixel unit Q; an end of the connection portion 32 close to the main body 31 is connected to a portion of the set edge M located at an overlapping position where the set edge M of the main body 31 overlaps with the circle around the center of the pixel unit Q; and the connection portion 32 extends along a tangent direction of the overlapping position of the circle around the center of the pixel unit Q. Thus, the uniformity of the arrangement of the sub-pixels P is improved.

In some embodiments, as shown in FIG. 7, among the pixel electrodes 301 of the four sub-pixels P included in one pixel unit Q, there exists at least a pair of two adjacent pixel electrodes 301 symmetrically arranged with respect to a reference line aa. The reference line aa is a bisector that is perpendicular to a direction in which the two adjacent pixel electrodes 301 are arranged and is located between the two adjacent pixel electrodes 301.

In some examples, as shown in FIG. 7, among the pixel electrodes 301 of the four sub-pixels P included in one pixel unit Q, there exist two pairs of two adjacent pixel electrodes 301 that are each symmetrically arranged with respect to the reference line aa. For example, in the pixel unit Q, the pixel electrode 301 of the sub-pixel P in the upper left and the pixel electrode 301 of the sub-pixel P in the upper right are symmetrically arranged with respect to the reference line aa, and the pixel electrode 301 of the sub-pixel P in the lower left and the pixel electrode 301 of the sub-pixel P in the lower right are symmetrically arranged with respect to the reference line aa.

In some examples, as shown in FIG. 6B, the four sub-pixels P in the figure may constitute one pixel unit Q; and in this pixel unit Q, there is a pair of two adjacent pixel electrodes 302 symmetrically arranged with respect to a bisector that is perpendicular to a direction in which the two adjacent pixel electrodes 301 are arranged and is located between the two adjacent pixel electrodes 301. For example, in the pixel unit Q, the pixel electrode 302 of the sub-pixel P in the lower left and the pixel electrode 302 of the sub-pixel P in the upper right are symmetrically arranged with respect to the bisector that is perpendicular to the direction in which the two adjacent pixel electrodes 301 are arranged and is located between the two adjacent pixel electrodes 301.

In this way, among the pixel electrodes 302 of the four sub-pixels P included in one pixel unit Q, at least one pair of two adjacent pixel electrodes 302 are symmetrically arranged with respect to the reference line aa. Therefore, the uniformity of the arrangement of the plurality of sub-pixels P is improved, the difficulty of the fabrication process of the plurality of sub-pixels P may be reduced, the complexity of the pattern of the mask for evaporation is reduced, and the patterning process is simplified.

In some embodiments, as shown in FIG. 7, each pixel unit Q includes at least a first sub-pixel P1 and a second sub-pixel P2 that emit light of the same color. The first sub-pixel P1 and the second sub-pixel P2 are distributed at two adjacent vertex corners in the pixel unit Q.

It will be noted that an orthographic projection of a pixel unit Q on the substrate 10 is in a shape of a rectangle, and the “two adjacent vertex corners in the pixel unit Q” refer to two vertex corners formed between one edge of the rectangle and two edges adjacent to the one edge.

In some examples, a direction in which the first sub-pixel P1 and the second sub-pixel P2 are arranged is parallel to the column direction Y in which the plurality of sub-pixels are arranged, as shown in FIG. 7. In some other examples, the direction in which the first sub-pixel P1 and the second sub-pixel P2 are arranged is parallel to the row direction X in which the plurality of sub-pixels are arranged. The embodiments of the present disclosure are not limited thereto.

For example, the first sub-pixel P1 and the second sub-pixel P2 may be blue sub-pixels. The efficiency of the light-emitting material of the blue sub-pixel is relatively low. By arranging two blue sub-pixels in each pixel unit Q, an effective light-emitting area of the blue sub-pixels in one pixel unit Q is increased, so as to ameliorate a problem of the color deviation caused by different light-emitting efficiencies of the red, green and blue sub-pixels.

In some implementations, when manufacturing the display panel 300, light-emitting portions 302 of different colors are formed using a fine metal mask (FMM). The fine metal mask has openings corresponding to a plurality of light-emitting portions 302

It can be understood that in order to prevent color crosstalk between two adjacent light-emitting devices 30, a certain distance is maintained between two adjacent pixel openings 401 of the pixel definition structure 40.

In the above embodiment of the present disclosure, the first sub-pixel P1 and the second sub-pixel P2 are located at two adjacent vertex corners in the pixel unit Q and are arranged adjacently, and the first sub-pixel P1 and the second sub-pixel P2 emit light of the same color. Therefore, in the process of forming the light-emitting portions 302 of the first sub-pixel P1 and the second sub-pixel P2, the problem of color crosstalk between the first sub-pixel P1 and the second sub-pixel P2 can be temporarily ignored, and in the fine metal mask used for forming the light-emitting portions 302 of the first sub-pixel P1 and the second sub-pixel P2, two openings corresponding to the light-emitting portions 302 of the first sub-pixel P1 and the second sub-pixel P2 can be connected to form a large opening (that is, a size of the opening of the fine metal mask at a position corresponding to the light-emitting portions 302 of the first sub-pixel P1 and the second sub-pixel P2 is increased). In an aspect, the manufacturing process of the fine metal mask is simplified. In another aspect, the difficulty of alignment of the fine metal mask is reduced, and the probability of color mixing is reduced.

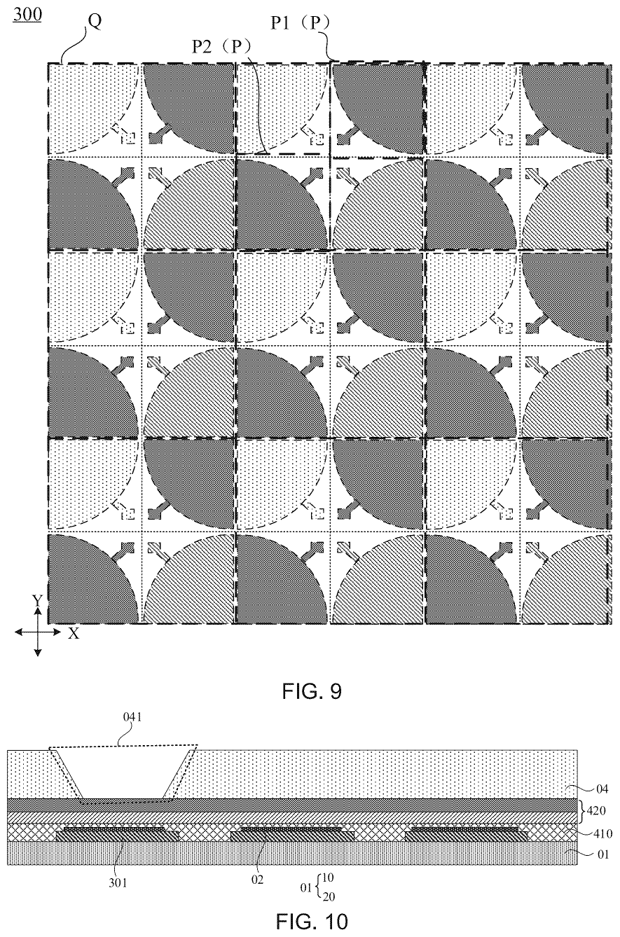

In some embodiments, as shown in FIG. 9, each pixel unit Q includes at least a first sub-pixel P1 and a second sub-pixel P2 that emit light of the same color, and the first sub-pixel P1 and the second sub-pixel P2 are distributed at two opposite vertex corners in the pixel unit Q.

It will be noted that an orthographic projection of a pixel unit Q on the substrate 10 is in a shape of a rectangle, and the “two opposite vertex corners in the pixel unit Q” refer to two vertex corners at two vertices of the rectangle that are not adjacent.

For example, the first sub-pixel P1 and the second sub-pixel P2 emitting light of the same color have the pixel electrodes 301 of the same shape and the same area, and have the light-emitting portions 302 of the same shape and the same area.

It can be understood that, each pixel unit Q includes the first sub-pixel P1 and the second sub-pixel P2 emitting light of the same color, and further includes two sub-pixels emitting light of colors that are different from the color of light emitted by the first sub-pixel P1 and the second sub-pixel P2; and colors of light emitted by the two sub-pixels are different. In this way, the first sub-pixel P1 and the second sub-pixel P2 emitting light of the same color are distributed at two opposite vertex corners in the pixel unit Q, and the first sub-pixel P1 is adjacent to other two sub-pixels in the pixel unit Q that emit light of a color different from the color of light emitted by the first sub-pixel P1, thereby achieving uniform color mixing and improving the display quality of the display panel 300.

In some embodiments, the via hole 501 in the insulating dielectric layer 50 is located in the avoidance region A2, and the connection portion 32 of the pixel electrode 301 is connected to the driving circuit layer 20 through the via hole 501.

Therefore, it is possible to ameliorate the problem that the connection portion 32 is disposed in the light-emitting region A1, causing a region of the pixel electrode 301 overlapping with the light-emitting portion 302 and the light-emitting portion 302 to be uneven, resulting in a phenomenon that the light-emitting surface of the light-emitting device 30 is not on the same surface, the light exit angles at different positions are different, and the color of the light-emitting device 30 observed by the observer has color deviation. Thus, the display effect of the display panel 300 is improved. In addition, it is also possible to avoid a situation where the light-emitting layer and the common electrode layer remain due to the step difference in the surface of the portion of the pixel electrode 301 exposed by the pixel opening 401 when the structures such as the light-emitting portions 302 and the common electrodes 303 are formed by the photolithography process. Thus, the yield of the display panel 300 is improved.

Embodiments of the present disclosure provide a method of manufacturing a display panel 300. The display panel 300 includes a plurality of rectangular sub-pixel regions AA; each sub-pixel region AA includes a light-emitting region A1 and an avoidance region A2 that are adjacent and connected to each other; the avoidance region A2 includes a vertex corner of a rectangle; and a region of the rectangle other than the avoidance region A2 is the light-emitting region A1. The method includes a1 to a2.

In a1, a substrate 10 is provided.

As for the structure of the substrate 10, reference can be made to the description in some of the above embodiments in the present disclosure, and details will not be repeated here.

In a2, a driving circuit layer 20, a plurality of pixel electrodes 301, a pixel definition structure 40, and a plurality of light-emitting portions 302 are formed on the substrate 10.

The pixel definition structure 40 is provided therein with a plurality of pixel openings 401. A pixel opening 401 is disposed in a light-emitting region A1, and a shape of the pixel opening 401 is the same as a shape of the light-emitting region A1. One pixel opening 401 corresponds to one pixel electrode 301. Each pixel opening 401 may fully expose one pixel electrode 301, or may only expose a part of one pixel electrode 301. The pixel electrode 301 includes a main body 31 and a connection portion 32 that are connected to each other. A shape of the main body 31 is the same as the shape of the pixel opening 401. The connection portion 32 is located in the avoidance region A2, and the connection portion 32 is connected to the driving circuit layer 20. One light-emitting portion 302 is disposed in one pixel opening 401.

A vertex corner of the rectangular sub-pixel region AA is set as the avoidance region A2, and the connection portion 32 of the pixel electrode 301 is disposed in the avoidance region A2. Therefore, it is possible to ameliorate the problem that the connection portion 32 is disposed in the light-emitting region A1, causing a region of the pixel electrode 301 overlapping with the light-emitting portion 302 and the light-emitting portion 302 to be uneven, resulting in a phenomenon that the light-emitting surface of the light-emitting device 30 is not on the same surface, the light exit angles at different positions are different, and the color of the light-emitting device 30 observed by the observer has color deviation. Thus, the display effect of the display panel 300 is improved. Moreover, it facilitates the subsequent fabrication of the structures such as the light-emitting portions 302 and the common electrodes 303, and avoids a situation where the light-emitting layer and the common electrode layer remain due to the step difference in the surface of the portion of the pixel electrode 301 exposed by the pixel opening 401 when the structures such as the light-emitting portions 302 and the common electrodes 303 are formed by the photolithography process. Thus, the yield of the display panel 300 is improved.

In some examples, the above step a2 may include steps a21 to a23.

In a21, the driving circuit layer 20 is formed on the substrate 10.

The driving circuit layer 20 includes a plurality of pixel circuits 210, a plurality of signal lines, and other structures. As for the detailed structure of the driving circuit layer 20, reference can be made to the description in some of the above embodiments in the present disclosure, and details will not be repeated here.

For examples, the substrate 10 and the driving circuit layer 20 constitute a backplane 01, as shown in FIG. 10.

In a22, the plurality of pixel electrodes 301 are formed on a side of the driving circuit layer 20 away from the substrate 10.

For example, a pixel electrode film may be formed by a sputtering process, and then the pixel electrode film is patterned to form the plurality of pixel electrodes 301 that are arranged at intervals. For example, a material of the pixel electrode 301 may be oxide, such as indium tin oxide (ITO), indium zinc oxide (IZO), etc. Alternatively, the material of the pixel electrode 301 may be a composite material, e.g., a composite material consisting of a metal material and an oxide material, such as silver (Ag)/ITO, aluminum (AI)/ITO, Ag/IZO, AI/IZO, etc.

In a23, the pixel definition structure 40 and the plurality of light-emitting portions 302 are formed on a side of the pixel electrodes 301 away from the driving circuit layer 20.

In some examples, in a case where the pixel definition structure 40 includes a pixel definition layer 41, forming the pixel definition structure 40 on the side of the pixel electrodes 301 away from the driving circuit layer 20 includes: forming a pixel definition film on the side of the pixel electrodes 301 away from the driving circuit layer 20, and patterning the pixel definition film to form the pixel definition layer 41 having the plurality of pixel openings 401.

A material of the pixel definition layer 41 includes an inorganic material or an organic insulating material.

For example, when the pixel definition layer 41 is made of an inorganic material, the pixel definition film with a certain thickness may be deposited on the side of the pixel electrodes 301 away from the driving circuit layer 20 by physical vapor deposition (PVD) or plasma enhanced chemical vapor deposition (PECVD), and then the pixel definition film is patterned by a photolithography process to form the pixel definition layer 41 having the plurality of pixel openings 401.

For example, when the pixel definition layer 41 is made of an organic insulating material, the pixel definition film with a certain thickness may be formed on the side of the pixel electrodes 301 away from the driving circuit layer 20 using a coating process, and then the pixel definition film is patterned by a photolithography process to form the pixel definition layer 41 having the plurality of pixel openings 401.

For example, the top view structure of the pixel definition layer 41 may be approximately a grid structure, and the plurality of pixel openings 401 constitute meshes of the grid structure.

It will be noted that, in the case where the pixel definition film is made of an inorganic material, the photolithography process may include: coating the pixel definition film with a photoresist; then providing a mask on a side of the photoresist away from the substrate, and exposing and developing the photoresist through the mask to remove an exposed part of the photoresist and retain an unexposed part of the photoresist, so that a patterned photoresist is formed; then etching the pixel definition film using the patterned photoresist as a mask to remove a part of the pixel definition film that is not blocked by the patterned photoresist, so that the plurality of pixel openings 401 are formed, and the pixel definition layer 41 is obtained. Then, the display panel 300 to be formed may be placed in a stripping solution to dissolve and strip off the patterned photoresist.

In the case where the pixel definition film is made of an organic material, the photolithography process may include: providing a mask on a side of the pixel definition film away from the substrate 10, exposing and developing the pixel definition film through the mask to remove an exposed part of the pixel definition film and to retain an unexposed part of the pixel definition film, so that the plurality of pixel openings 401 are formed, and the pixel definition layer 41 is obtained.

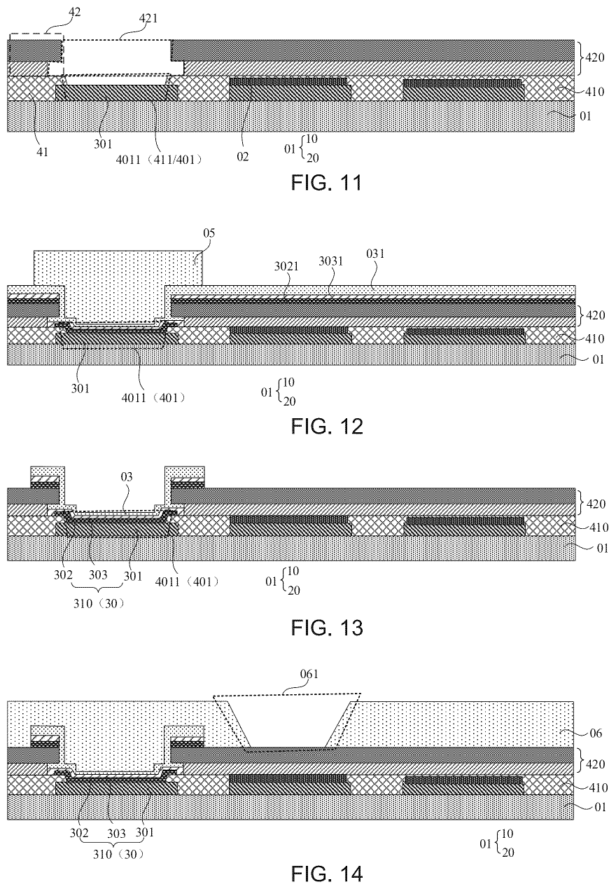

In some other examples, in a case where the pixel definition structure 40 includes a pixel definition layer 41 and an isolation structure 42, a pixel definition film 410 and an isolation film 420 may be sequentially formed using a sputtering process, as shown in FIGS. 10 and 11. Then, the pixel definition film 410 and the isolation film 420 are patterned (e.g., etched) to form the pixel definition layer 41 having a plurality of first openings 411 and the isolation structure 42 having a plurality of second openings 421. One first opening 411 is arranged corresponding to one second opening 421, and an orthogonal projection of the first opening 411 on the substrate 10 is located within an orthogonal projection of the second opening 421 on the substrate 10. In the case where the pixel definition structure 40 includes the pixel definition layer 41 and the isolation structure 42, the pixel openings 401 included in the pixel definition structure 40 can be understood as the first openings 411 provided in the pixel definition layer 41.

In a case where the isolation structure 42 is a two-layer structure, forming the isolation film 420 by the sputtering process may include: sequentially forming a first isolation sub-film and a second isolation sub-film on the pixel definition film.

For example, the first isolation sub-film is made of titanium (Ti), and the second isolation sub-film may be made of aluminum (Al). Since Ti and Al have different wet etching rates, during the process of etching the first isolation sub-film and the second isolation sub-film, the second isolation sub-film may be less affected by the etching, and the first isolation sub-film may be etched faster, which is convenient for forming an undercut structure (e.g., a “T” shaped structure). Those skilled in the art can also select other suitable materials as long as the above technical effects can be achieved. The embodiments of the present disclosure are not limited thereto.

In some examples, as shown in FIG. 10, before forming the pixel definition structure 40 and the plurality of light-emitting portions 302 on the side of the pixel electrodes 301 away from the driving circuit layer 20, the method further includes: forming a plurality of first sacrificial layers 02 on the side of the plurality of pixel electrodes 301 away from the driving circuit layer 20, so as to protect the pixel electrodes 301 and avoid damage to the pixel electrodes 301 when forming subsequent film layer(s) (e.g., the pixel definition structure 40).

For example, as shown in FIG. 10, an orthographic projection of a first sacrificial layer 02 on the substrate 10 is located within the orthographic projection of the pixel electrode 301 on the substrate 10.

It will be noted that the plurality of light-emitting devices 30 have a plurality of colors. In the step a23, pixel openings 401 corresponding to light-emitting devices 30 of different colors are formed separately. After pixel openings 401 corresponding to light-emitting devices 30 of each preset color are formed, a light-emitting portion 302 and a common electrode 303 of a light-emitting device 30 of the preset color are formed in a pixel opening 401. When forming light-emitting devices 30 of a certain color, pixel openings 401 corresponding to the light-emitting devices 30 of that color are firstly formed each time, and then light-emitting portions 302 and common electrodes 303 of the light-emitting devices 30 of that color are formed in the pixel openings 401. Then, pixel openings 401 corresponding to light-emitting devices 30 of another color and light-emitting portions 302 located in the pixel openings 401 are formed.

In some examples, after the light-emitting portions 302 and the common electrodes 303 of the light-emitting devices 30 of each preset color are formed, an encapsulation sub-layer 03 needs to be formed. For example, the encapsulation sub-layer 03 may be made of an inorganic material. In a case where the encapsulation sub-layer is made of an inorganic material, the encapsulation sub-layer 03 may be formed by deposition (CVD).

For example, the plurality of light-emitting devices 30 include at least a plurality of first light-emitting devices 310, a plurality of second light-emitting devices 320, and a plurality of third light-emitting devices 330. The plurality of first light-emitting devices 310, the plurality of second light-emitting devices 320, and the plurality of third light-emitting devices 330 emit light of different colors. For example, the first light-emitting devices 310 may emit red light, the second light-emitting devices 320 may emit blue light, and the third light-emitting devices 330 may emit green light.

In some examples, the above step a23 may include steps a231 to a237.

In a231, referring to FIGS. 10 and 11, a plurality of pixel openings 401 corresponding to the first light-emitting devices 310 are formed.

For convenience of the description, the pixel openings 401 corresponding to the first light-emitting devices 310 are defined as first-type pixel openings 4011; pixel openings 401 corresponding to the second light-emitting devices 320 are defined as second-type pixel openings 4012; and pixel openings 401 corresponding to the third light-emitting devices 330 are defined as third-type pixel openings 4013.

Referring to FIGS. 10 and 11, forming the plurality of pixel openings 401 corresponding to the first light-emitting devices 30 may include: forming a first shielding layer 04 on a side of the isolation film 420 away from the pixel definition film 410, where the first shielding layer 04 has a plurality of first sub-openings 041 arranged opposite to pixel openings 401 to be formed, one first sub-opening 041 is arranged opposite to one pixel opening 401 to be formed, and an orthogonal projection of the pixel opening 401 to be formed on the substrate 10 is located within an orthogonal projection of the first sub-opening 041 on the substrate 10; and etching portions of the pixel definition film 410 and the isolation film 420 that are not covered by the first shielding layer 04 using the first shielding layer 04 as a mask, to form the pixel definition layer 41 having a plurality of first openings 411 and the isolation structure 42 having a plurality of second openings 421. The pixel openings 401 included in the pixel definition structure 40 can be understood as the first openings 411 provided in the pixel definition layer 41.

For example, the first shielding layer 04 may be a photoresist layer.

For example, the method further includes: in the case where the plurality of first sacrificial layers 02 are formed on the side of the plurality of pixel electrodes 301 away from the driving circuit layer 20, etching and removing first sacrificial layers 02 corresponding to pixel electrodes 301 of the first light-emitting devices 310.

It can be understood that after the pixel openings 401 (i.e., the first-type pixel openings 4011) corresponding to the first light-emitting devices 310 are formed, the first shielding layers 04 are removed.

In a232, as shown in FIG. 12, a light-emitting layer 3021, a common electrode layer 3031 and a first encapsulation film 031 for the first light-emitting devices 310 are formed in the pixel openings 401 corresponding to the first light-emitting devices 310. The first encapsulation film 031 is used to form the encapsulation sub-layers 03 corresponding to the first light-emitting devices 30.

For example, a part of the light-emitting layer 3021 is located in the pixel openings 401, and another part of the light-emitting layer 3021 is located on a side of the isolation film away from the substrate 10; a part of the common electrode layer 3031 is located in the pixel openings 401, and another part of the common electrode layer 3031 is located on the side of the isolation film away from the substrate 10; and a part of the first encapsulation film 031 is located in the pixel openings 401, and another part of the first encapsulation film 031 is located on the side of the isolation film away from the substrate 10.

The light-emitting layer 3021 and the common electrode layer 3031 may be formed by evaporation. The isolation structure 42 and the pixel definition layer 41 have a step difference at the pixel opening 401 (for example, a side surface of the isolation structure 42 away from the substrate 10 and a side surface of the pixel definition layer 41 away from the substrate 10 are not on the same horizontal plane), and thicknesses of the light-emitting layer 3021, the common electrode layer 3031 and the first encapsulation film 031 are small. Therefore, the part of the light-emitting layer 3021 located in the pixel openings 401 is disconnected from the part of the light-emitting layer 3021 located on the side of the isolation film away from the substrate 10; the part of the common electrode layer 3031 located in the pixel openings 401 is disconnected from the part of the common electrode layer 3031 located on the side of the isolation film away from the substrate 10; and the part of the first encapsulation film 031 located in the pixel openings 401 is disconnected from the part of the first encapsulation film 031 located on the side of the isolation film away from the substrate 10.

In some examples, after the step a232, the method further includes: forming a covering film layer on a side of the first encapsulation film 031 away from the common electrode layer 3031. A part of the covering film layer is located in the pixel openings 401, and another part of the covering film layer is located on the side of the isolation film away from the substrate 10. The covering film layer is used to protect the common electrode layer 3031 to prevent the common electrode layer 3031 from being damaged by subsequent manufacturing processes.

In a233, as shown in FIG. 12, a first photoresist layer 05 is formed on a side of the first encapsulation film 031 away from the common electrode layer 3031. The first photoresist layer 05 covers the first-type pixel opening 4011 and a portion of the pixel definition structure 40 located around the first-type pixel opening 4011.

For example, a first photoresist film is formed on the side of the first encapsulation film 031 away from the common electrode layer 3031 using a coating process, and then the first photoresist film is exposed and developed to form the first photoresist layer 05.

In a234, as shown in FIG. 13, a part of the light-emitting layer 3021 for the first light-emitting devices 310 that is not covered by the first photoresist layer 05, a part of the common electrode layer 3031 that is not covered by the first photoresist layer 05, and a part of the first encapsulation film 031 that is not covered by the first photoresist layer 05 are etched using the first photoresist layer 05 as a mask, to remove material layers in a region outside the first-type pixel openings 4011, thereby obtaining light-emitting portions 302, common electrodes 303 and encapsulation sub-layers 03 of the first light-emitting devices 310.

It can be understood that after the light-emitting portions 302, the common electrodes 303 and the encapsulation sub-layers 03 of the first light-emitting devices 310 are formed, the first photoresist layer 05 is removed.

Thus, the first light-emitting devices 310 are formed.

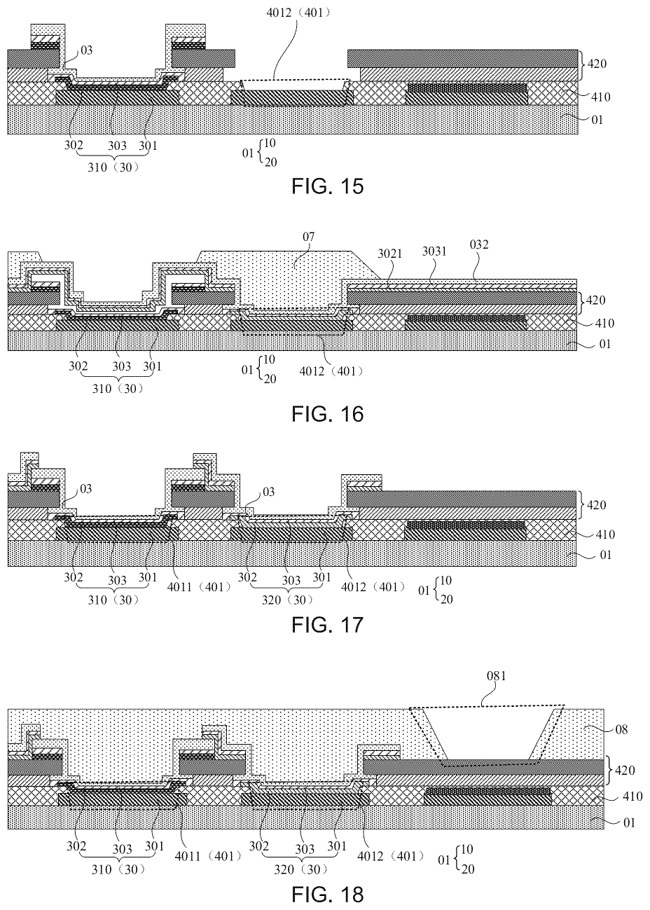

In a235, referring to FIGS. 14 and 15, a plurality of pixel openings 401 corresponding to the second light-emitting devices 320 (i.e., the second-type pixel openings 4012) are formed.

Referring to FIGS. 14 and 15, forming the plurality of pixel openings 401 corresponding to the second light-emitting devices 320 may include: forming a second shielding layer 06 on the side of the isolation film away from the pixel definition film, where the second shielding layer 06 has a plurality of second sub-openings 061 arranged opposite to pixel openings 401 to be formed, one second sub-opening 061 is arranged opposite to one pixel opening 401 to be formed, and an orthogonal projection of the pixel opening 401 to be formed on the substrate 10 is located within an orthogonal projection of the second sub-opening 061 on the substrate 10; and etching portions of the pixel definition film 410 and the isolation film 420 that are not covered by the second shielding layer 06 using the second shielding layer 06 as a mask, to form the pixel definition layer 41 having a plurality of first openings 411 and the isolation structure 42 having a plurality of second openings 421. The pixel openings 401 included in the pixel definition structure 40 can be understood as the first openings 411 provided in the pixel definition layer 41.

For example, the second shielding layer 06 may be a photoresist layer.

It can be understood that after the second-type pixel openings 4012 are formed, the second shielding layer 06 is removed.

In a236, as shown in FIG. 16, a light-emitting layer 3021, a common electrode layer 3031 and a second encapsulation film 032 for the second light-emitting devices 320 are formed in the pixel openings 401 corresponding to the second light-emitting devices 320. The second encapsulation film 032 is used to form the encapsulation sub-layers 03 corresponding to the second light-emitting devices 320.

In a237, a second photoresist layer 07 is formed on a side of the second encapsulation film 032 away from the common electrode layer 3031. The second photoresist layer 07 covers the second-type pixel opening 412 and a portion of the pixel definition structure 40 located around the second-type pixel opening 412.

In a238, as shown in FIG. 17, a part of the light-emitting layer 3021 that is not covered by the second photoresist layer 07, a part of the common electrode layer 3031 that is not covered by the second photoresist layer 07, and a part of the second encapsulation film 032 that is not covered by the second photoresist layer 07 are etched using the second photoresist layer 07 as a mask, to form light-emitting portions 302, common electrodes 303 and encapsulation sub-layers 03 of the second light-emitting devices 320.

It can be understood that after the light-emitting portions 302, the common electrodes 303 and the encapsulation sub-layers 03 of the second light-emitting devices 320 are formed, the second photoresist layer 07 is removed.

Thus, the second light-emitting devices 320 are formed.

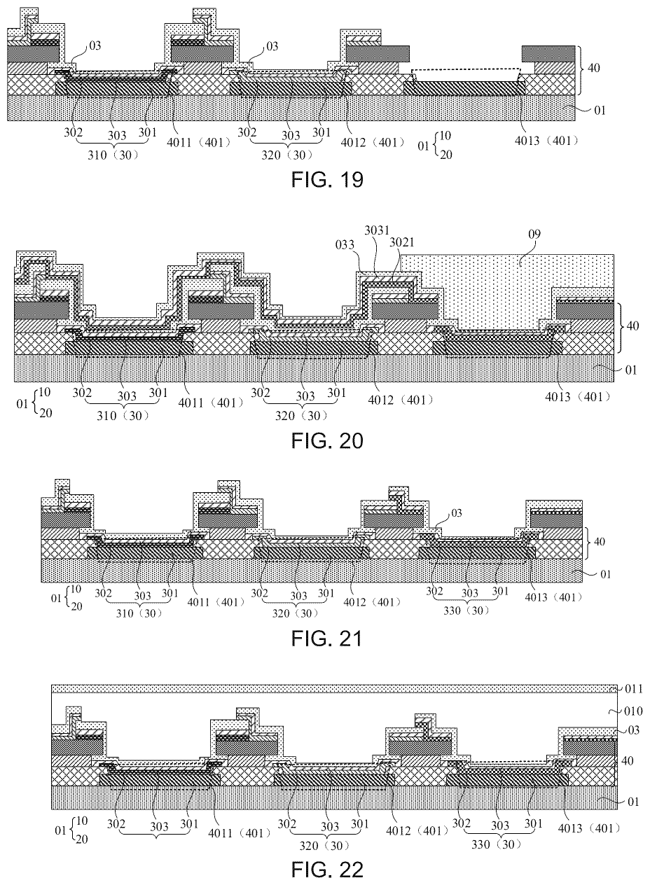

In a239, referring to FIGS. 18 and 19, a plurality of pixel openings 401 corresponding to the third light-emitting devices 330 (i.e., the third-type pixel openings 4013) are formed.

Referring to FIGS. 18 and 19, forming the plurality of pixel openings 401 corresponding to the third light-emitting devices 330 may include: forming a third shielding layer 08 on the side of the isolation film away from the pixel definition film, where the third shielding layer 08 has a plurality of third sub-openings 081 arranged opposite to pixel openings 401 to be formed, one third sub-opening 081 is arranged opposite to one pixel opening 401 to be formed, and an orthogonal projection of the pixel opening 401 to be formed on the substrate 10 is located within an orthogonal projection of the third sub-opening 081 on the substrate 10; and etching portions of the pixel definition film 410 and the isolation film 420 that are not covered by the third shielding layer 08 using the third shielding layer 08 as a mask, to form the pixel definition layer 41 having a plurality of first openings 411 and the isolation structure 42 having a plurality of second openings 421. The pixel openings 401 included in the pixel definition structure 40 can be understood as the first openings 411 provided in the pixel definition layer 41.

For example, the third shielding layer 08 may be a photoresist layer.

It can be understood that after the third-type pixel openings 4013 are formed, the third shielding layer 08 is removed.

In a2310, as shown in FIG. 20, a light-emitting layer 3021, a common electrode layer 3031 and a third encapsulation film 033 for the third light-emitting devices 330 are formed in the pixel openings 401 corresponding to the third light-emitting devices 330. The third encapsulation film 033 is used to form the encapsulation sub-layers 03 corresponding to the third light-emitting devices 330.

In a2311, as shown in FIG. 20, a third photoresist layer 09 is formed on a side of the third encapsulation film 033 away from the common electrode layer 3031. The third photoresist layer 09 covers the third-type pixel opening 4013 and a portion of the pixel definition structure 40 located around the third-type pixel opening 4013.

In a2312, as shown in FIG. 21, a part of the light-emitting layer 3021 that is not covered by the third photoresist layer 09, a part of the common electrode layer 3031 that is not covered by the third photoresist layer 09, and a part of the third encapsulation film 033 that is not covered by the third photoresist layer 09 are etched using the third photoresist layer 09 as a mask, to form light-emitting portions 302, common electrodes 303 and encapsulation sub-layers 03 of the third light-emitting devices 330.

It can be understood that after the light-emitting portions 302, the common electrodes 303 and the encapsulation sub-layers 03 of the third light-emitting devices 330 are formed, the third photoresist layer 09 is removed.

Thus, the third light-emitting devices 330 are formed.

In some examples, as shown in FIG. 22, after the step a2312, the method further includes: forming an organic encapsulation layer 010 and an inorganic encapsulation layer 011 on a side of a plurality of encapsulation sub-layers 03 away from the substrate 10.

For example, a material of the organic encapsulation layer 010 includes a combination of one or more of an acrylic-based polymer, a silicon-based polymer and an epoxy-based polymer. The above material is formed on all of the encapsulation sub-layers 03 by inkjet printing (IJP), and ultraviolet (UV) curing is performed, so that the organic encapsulation layer 010 is formed.

For example, a material of the inorganic encapsulation layer 011 includes a combination of one or more of silicon nitride (SiNx), silicon oxide (SiOx) or silicon oxynitride (SiON). The inorganic encapsulation layer 011 may be formed by chemical vapor deposition (CVD).

In some examples, before forming the plurality of pixel electrodes 301, the pixel definition structure 40, and the light-emitting portions 302 on the side of the driving circuit layer 20 away from the substrate 10, an insulating dielectric layer 50 may be formed on the side of the driving circuit layer 20 away from the substrate 10.

For example, the insulating dielectric layer 50 may make the surface of the driving circuit layer 20 flat, which facilitates the subsequent fabrication of structures such as the pixel electrodes 301. A material of the insulating dielectric layer 50 may include an organic material. The insulating dielectric layer 50 may be formed by inkjet printing.

In the method of manufacturing the display panel 300 provided in the embodiments of the present disclosure, a vertex corner of the rectangular sub-pixel region AA is set as the avoidance region A2, and the connection portion 32 of the pixel electrode 301 is disposed in the avoidance region A2 and is electrically connected to the driving circuit layer 20 through the via hole 501 of the insulating dielectric layer 50 located in the avoidance region A2. In an aspect, it is possible to ameliorate the problem that the connection portion 32 is disposed in the light-emitting region A1, causing a region of the pixel electrode 301 overlapping with the light-emitting portion 302 and the light-emitting portion 302 to be uneven, resulting in a phenomenon that the light-emitting surface of the light-emitting device 30 is not on the same surface, the light exit angles at different positions are different, and the color of the light-emitting device 30 observed by the observer has color deviation. Thus, the display effect of the display panel 300 is improved.

In another aspect, when the light-emitting portions 302 and the common electrodes 303 are formed by the photolithography process, since a vertex corner of the rectangular sub-pixel region AA is set as the avoidance region A2 and the connection portion 32 of the pixel electrode 301 is disposed in the avoidance region A2, it facilitates the subsequent fabrication of the structures such as the light-emitting portions 302 and the common electrodes 303, and avoids a situation where the light-emitting layer and the common electrode layer remain due to the step difference in the surface of the portion of the pixel electrode 301 exposed by the pixel opening 401 when the structures such as the light-emitting portions 302 and the common electrodes 303 are formed. In addition, since the light-emitting portions 302 and the common electrodes 303 are formed by the photolithography process, the difficulty of manufacturing the display panel 300 is reduced, and the manufacturing cost of the display panel 300 is reduced. Thus, the arrangement density of the light-emitting devices in the display panel 300 is not limited by the size of the FMM, which is conducive to improving the PPI of the display panel 300; and there is no need to use the FMM, which avoids the problem of inaccurate alignment.

The foregoing descriptions are merely specific implementations of the present disclosure, but the protection scope of the present disclosure is not limited thereto. Any changes or replacements that a person skilled in the art could conceive of within the technical scope of the present disclosure shall be included in the protection scope of the present disclosure. Therefore, the protection scope of the present disclosure should be determined by the protection scope of the claims.

What is claimed is:

1. A display panel, comprising a plurality of rectangular sub-pixel regions, wherein each sub-pixel region includes a light-emitting region and an avoidance region that are adjacent and connected to each other, the avoidance region includes a vertex corner of a rectangle, and a region of the rectangle other than the avoidance region is the light-emitting region;
the display panel comprising:
a substrate;
a driving circuit layer disposed on the substrate;
a plurality of pixel electrodes disposed on a side of the driving circuit layer away from the substrate;
a pixel definition structure disposed on a side of the plurality of pixel electrodes away from the driving circuit layer, wherein the pixel definition structure is provided therein with a pixel opening in the light-emitting region, and a shape of the pixel opening is the same as a shape of the light-emitting region; and
a plurality of light-emitting portions, one light-emitting portion being disposed in one pixel opening;
wherein one pixel opening corresponds to one pixel electrode, the pixel electrode includes a main body and a connection portion that are connected to each other, a shape of the main body is the same as the shape of the pixel opening, the connection portion is located in the avoidance region, and the connection portion is connected to the driving circuit layer.

2. The display panel according to claim 1, wherein a boundary of the main body includes two perpendicular edges and a set edge that are connected, ends of the two perpendicular edges are connected and form a right angle, two ends of the two perpendicular edges that are far away from each other are respectively connected to two ends of the set edge, and the set edge includes an arc segment;
an end of the connection portion is connected to the arc segment of the boundary of the main body, and another end of the connection portion extends in a direction away from the main body and is connected to the driving circuit layer.

3. The display panel according to claim 2, wherein two ends of the arc segment are respectively connected to the two ends of the two perpendicular edges that are far away from each other.

4. The display panel according to claim 2, wherein the set edge further includes two straight segments, the two straight segments are respectively located on two ends of the arc segment, and a straight segment is connected to an end of the arc segment and an end of one of the two perpendicular edges.

5. The display panel according to claim 3, wherein a radius of curvature of the arc segment is less than or equal to a size of a perpendicular edge of the two perpendicular edges.

6. The display panel according to claim 1, wherein an orthographic projection of the main body on the substrate is fan-shaped or approximately fan-shaped, or is in a shape of a pentagon obtained by cutting off a corner of a rectangle.

7. The display panel according to claim 2, wherein the display panel comprises a plurality of pixel units, each pixel unit includes four sub-pixels, the four sub-pixels are arranged in a 2×2 matrix, and each sub-pixel includes a pixel electrode and a corresponding light-emitting portion;
set edges of main bodies of pixel electrodes of the four sub-pixels are close to each other and enclose an accommodation region; and
connection portions of the pixel electrodes of the four sub-pixels are arranged close to each other and are located in the accommodation region.

8. The display panel according to claim 7, wherein a shape formed by a line connecting an end of each of the connection portions of the four sub-pixels that is away from a respective main body is a square.

9. The display panel according to claim 2, wherein the display panel comprises a plurality of pixel units, each pixel unit includes four sub-pixels, the four sub-pixels are arranged in a 2×2 matrix, and each sub-pixel includes a pixel electrode and a corresponding light-emitting portion; and
along a circumferential direction around a center of the pixel unit, main bodies and connection portions of four pixel electrodes of the four sub-pixels are arranged alternately.

10. The display panel according to claim 9, wherein a connection portion extends along a tangential direction of the circumferential direction around the center of the pixel unit.

11. The display panel according to claim 7, wherein among the pixel electrodes of the four sub-pixels, at least a pair of two adjacent pixel electrodes are symmetrically arranged with respect to a reference line, wherein the reference line is a bisector being perpendicular to a direction in which the two adjacent pixel electrodes are arranged and being located between the two adjacent pixel electrodes.

12. The display panel according to claim 11, wherein each pixel unit includes at least a first sub-pixel and a second sub-pixel that emit light of a same color, and the first sub-pixel and the second sub-pixel are respectively distributed at two adjacent vertex corners in the pixel unit.

13. The display panel according to claim 11, wherein each pixel unit includes at least a first sub-pixel and a second sub-pixel that emit light of a same color, and the first sub-pixel and the second sub-pixel are respectively distributed at two opposite corners in the pixel unit.

14. The display panel according to claim 1, further comprising: an insulating dielectric layer located between the driving circuit layer and the pixel electrodes, wherein the insulating dielectric layer is provided therein with a via hole, the connection portion is connected to the driving circuit layer through the via hole, and the via hole is located in the avoidance region.

15. A display apparatus, comprising:
the display panel according to claim 1; and
a cover plate disposed on a light-exit side of the display panel.

16. The display apparatus according to claim 15, wherein a boundary of the main body includes two perpendicular edges and a set edge that are connected, ends of the two perpendicular edges are connected and form a right angle, two ends of the two perpendicular edges that are far away from each other are respectively connected to two ends of the set edge, and the set edge includes an arc segment;
an end of the connection portion is connected to the arc segment of the boundary of the main body, and another end of the connection portion extends in a direction away from the main body and is connected to the driving circuit layer.

17. The display panel according to claim 1, wherein the pixel definition structure includes:
a pixel definition layer having a plurality of first openings, one first opening exposing a part of at least part of one pixel electrode; and
an isolation structure located on a side of the pixel definition layer away from the plurality of pixel electrodes and having a plurality of second openings, wherein one first opening corresponds to one second opening, and an orthogonal projection of the first opening on the substrate is located within an orthogonal projection of the second opening on the substrate.

18. The display panel according to claim 17, further comprising:
a plurality of common electrodes disposed on a side of the plurality of light-emitting portions away from the plurality of pixel electrodes, wherein overlapping portions of a pixel electrode, a light-emitting portion, and a common electrode form a light-emitting device.

19. The display panel according to claim 18, wherein any two adjacent common electrodes among the plurality of common electrodes are separated by the isolation structure.

20. The display panel according to claim 1, wherein an area of the light-emitting region is approximately the same as an area of the main body.
